(19) United States
(12) Patent Application Publication
(10) Pub. No.: US 2007/0046199 A1
(43) Pub. Date: Mar. 1, 2007

(54) Organic electro-luminescence display apparatus and organic thin film transistor for the same

(76) Inventors: Won-tae Lee, Hwaseong-si (KR); Seong-eui Lee, Seongnam-si (KR)

Correspondence Address: CANTOR COLBURN, LLP, 55 GRIFFIN ROAD SOUTH, BLOOMFIELD, CT, 06002, US

(21) Appl. No.: 11/509,481

(22) Filed: Aug. 24, 2006

(30) Foreign Application Priority Data
Aug. 24, 2005 (KR) 10-2005-0078041

(51) Int. Cl. H01J 1/62

(52) U.S. Cl. 313/512; 313/503

(57) ABSTRACT

An organic electro-luminescence display apparatus and an organic thin film transistor for the same include: a first electrode-layer supplying holes; a second electrode layer supplying electrons; an organic thin film layer disposed between the first electrode layer and the second electrode layer, the organic thin film layer emits light through the recombination of the holes and the electrons; and a sealing protection layer insulating at least the second electrode layer and the organic thin film layer from an external gas, wherein the sealing protection layer includes at least a LaF₃ layer. Since the penetration of harmful materials such as moisture or oxygen is prevented, the organic electro-luminescence display apparatus can provide constant performance. In addition, since an additional sealing structure is not required, the organic electro-luminescence display apparatus is lighter, thinner, and less costly to manufacture.

This application claims priority to Korean Patent Application No. 10-2005-0078041, filed on Aug. 24, 2005, and all the benefits accruing therefrom under 35 U.S.C. §119, the contents of which in its entirety are herein incorporated by reference.

### BACKGROUND OF THE INVENTION

1. Field of the Invention

The present invention relates to an organic electro-luminescence display apparatus and an organic thin film transistor for the same, and more particularly, to an organic electro-luminescence display apparatus providing constant performance by using a structure that prevents the penetration of harmful materials such as moisture or oxygen, and an organic thin film transistor for the same.

2. Description of the Related Art

Flat panel display apparatuses such as organic electro-luminescence display apparatuses, liquid crystal display apparatuses, or inorganic electro-luminescence display apparatuses are classified as either a passive driving type flat panel display apparatus or an active driving type flat panel display apparatus, dependent on their driving types. The active driving type flat panel display apparatuses control input signals for each pixel using thin film transistors (“TFTs”) that can process many signals, and thus, are frequently used for realizing a moving picture. However, an organic thin film transistor, including organic materials for forming a semiconductor active layer, malfunctions when oxygen and moisture penetrate into a thin film structure and react with a layer structure of the organic thin film transistor.

FIG. 1 is a cross-sectional view of a conventional organic electro-luminescence display apparatus. Referring to FIG. 1, a first electrode layer 21 which is formed of, for example, indium tin oxide (ITO), and supplies holes, a hole transport layer 23, a light emitting layer 25 which emits light through the recombination of the holes and the electrons, an electron transport layer 27, a second electrode layer 29, which is formed of a metal electrode supplying electrons, all of which are sequentially formed on a glass substrate 10. In the light emitting layer 25, light is generated through recombining holes inserted from the first electrode layer 21 and electrons inserted from the second electrode layer 29. For the recombination, the first electrode layer 21 may be made of a material having a high work function, and the second electrode layer 29 may be made of a material having a low work function such as a metal. Since the second electrode layer 29 has characteristics of high activity and chemical instability, the second electrode layer 29 easily reacts with external moisture or oxygen. Thus the metal second electrode layer 29 is easily oxidized or corroded. When moisture or oxygen penetrates into an organic thin film layer 22 including the light emitting layer 25, the structure of the organic thin film layer 22 changes, thereby degrading a light emitting characteristic of the apparatus. Conventionally, the organic thin film layer 22 and the second electrode layer 29 are sealed with a capping element 30 made of metal or plastic to isolate the organic thin film layer 22 and the second electrode layer 29 from external harmful materials. The capping element 30 is attached to the first electrode layer 21 using an adhesive agent 35, for example, an ultraviolet (“UV”) adhesive, and moisture absorbents 40 are disposed in the capping element 30. Specifically, an inlet to a cavity is prepared in the upper side of the capping element 30, and the moisture absorbent 40 are inserted through the inlet and fixed using tapes having pores.

However, as described above, the capping element 30 isolating the layers from external gas such as moisture or oxygen, increases the weight and volume of the apparatus, thereby making it difficult to manufacture a lightweight, thin, simple and small display apparatus. In addition, since additional processes such as a process of attaching the capping element 30 or a process of mounting the moisture absorbents 40 are required, the manufacturing time becomes longer and the manufacturing yield becomes lower. Furthermore, the reliability of products is degraded due to the additional elements.

### BRIEF SUMMARY OF THE INVENTION

An aspect of the present invention provides constant performance of an organic electro-luminescence display apparatus by using a structure that prevents the penetration of impurities such as moisture or oxygen, and an organic thin film transistor for the same.

An aspect of the present invention also provides an organic electro-luminescence display apparatus having a simple structure, thereby reducing manufacturing processes and costs.

According to an exemplary embodiment of the present invention, there is provided an organic electro-luminescence display apparatus including: a first electrode layer supplying holes; a second electrode layer supplying electrons; an organic thin film layer disposed between the first electrode layer and the second electrode layer, and the organic thin film layer emits light through the recombination of the holes and the electrons; and a sealing protection layer insulating at least the second electrode layer and the organic thin film layer from an external gas, wherein the sealing protection layer includes at least a LaF₃ layer.

The apparatus may further include an insulation substrate acting also as a supporting structure, wherein the first electrode layer, organic thin film layer, and second electrode layer are sequentially stacked on the insulation substrate, wherein the sealing protection layer seals an outer region ranging from the lateral sides of the organic thin film layer and the second electrode layer to the upper sides of the second electrode layer.

The sealing protection layer may have a monolayer structure of the LaF₃ layer, a multilayer structure including at least two layers of the LaF₃ layer and one of an organic layer and an inorganic layer, or a multilayer structure including at least three layers of the LaF₃ layer, an organic layer and an inorganic layer. The inorganic layer may be formed of one of silicon nitride and silicon oxide.

The LaF₃ layer may have a thickness of at least 30 nm. The LaF₃ layer may be formed using one deposition method selected from the group consisting of physical vapor deposition (PVD) including ion beam deposition and chemical vapor deposition (CVD) including low pressure CVD (LPCVD) and plasma enhanced CVD (PECVD).

According to another exemplary embodiment of the present invention, there is provided an organic thin film transistor which includes a gate electrode formed on an insulation substrate, an organic insulation layer covering the gate electrode, a source electrode and a drain electrode formed on the upper surface of the organic insulation layer, and an organic semiconductor layer formed on the source and drain electrodes. The organic thin film transistor includes: a passivation layer which includes at least a LaF₃ layer and is formed on the upper surface of the organic insulation layer or on the upper surface of the organic semiconductor.

The passivation layer may have a monolayer structure of the LaF₃ layer, a multilayer structure including at least two layers of the LaF₃ layer and one of an organic layer and an inorganic layer, or a multilayer structure including at least three layers of the LaF₃ layer, the organic layer and the inorganic layer. The inorganic layer may be formed of one of silicon nitride and silicon oxide.

The passivation layer may cover the source and drain electrodes the organic semiconductor layer formed between the source and drain electrodes. The LaF₃ layer may have a thickness of at least 30 nm.

The LaF₃ layer may be formed using one deposition method selected from the group consisting of physical vapor deposition (PVD) including ion beam deposition and chemical vapor deposition (CVD) including low pressure CVD (LPCVD) and plasma enhanced CVD (PECVD).

### BRIEF DESCRIPTION OF THE DRAWINGS

The above and other aspects, features and advantages of the present invention will become more apparent by describing in detail exemplary embodiments thereof with reference to the attached drawings in which:

FIG. 1 is a cross-sectional view of a conventional organic electro-luminescence display apparatus;

FIG. 2 is a cross-sectional view of an organic electro-luminescence display apparatus according to an exemplary embodiment of the present invention;

FIG. 3 is a graph illustrating the degree of protection against moisture of LaF₃ layers;

FIG. 4 is a cross-sectional view of an organic electro-luminescence display apparatus according to another exemplary embodiment of the present invention; and

FIG. 5 is a cross-sectional view of an organic thin film transistor according to an exemplary embodiment of the present invention.

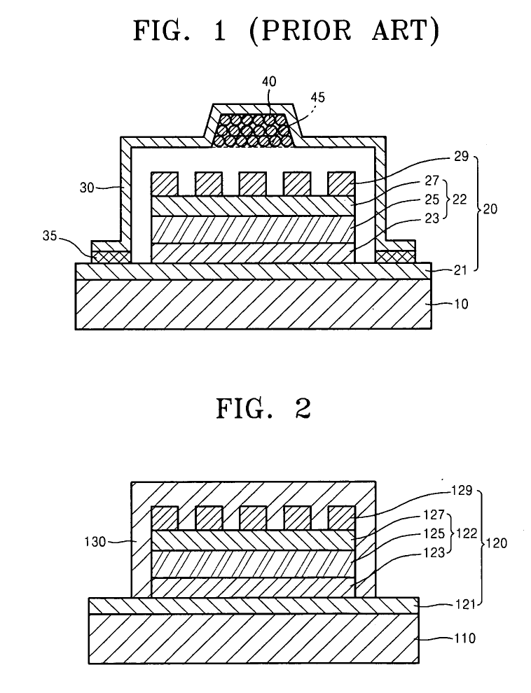

### DETAILED DESCRIPTION OF THE INVENTION

Hereinafter, the present invention will be described more fully with reference to the accompanying drawings, in which exemplary embodiments of the invention are shown.

FIG. 2 is a cross-sectional view of an organic electro-luminescence display apparatus according to an exemplary embodiment of the present invention. The organic electro-luminescence display apparatus includes an insulation substrate 110, which is formed of glass or plastic and acts as a supporter, and an organic light emitting device 120 formed on the insulation substrate 110. The insulation substrate 110 may be formed of transparent or translucent glass, or flexible plastic such as polyethylene terephthalate (PET) or polycarbonate.

The organic light emitting device 120 emits red, green or blue light according to a current flow to display predetermined image information, and includes a first electrode layer 121 supplying holes, (e.g., an anode), a second electrode layer 129 supplying electrons, (e.g., a cathode, and an organic thin film layer 122 which is disposed between the first electrode layer 121 and the second electrode layer 129 and has a light emitting region. The first electrode layer 121 may be formed of a material having a high work function, for example, indium-tin oxide (ITO) that is usually used for a transparent electrode.

The organic thin film layer 122 formed on the first electrode layer 121 may be formed of a plurality of low molecular organic layers or a plurality of high molecular organic layers. When using the low molecular organic layers, an organic thin film layer may have a stacked structure of a hole injection layer, a hole transport layer, an organic light emitting layer, an electron transport layer and an electron injection layer. The organic thin film layer 122 in the FIG. 2 has a hole transport layer 123, an organic light emitting layer 125 and an electron transport layer 127. When using high molecular organic layers, the organic thin film layer 122 may typically have a structure of a hole transport layer and a light emission layer. However, the organic thin film layer 122 is not limited thereto, but may have a monolayer structure of the organic light emission layer 122, a double layer structure of the hole transport layer 123 and the organic light emission layer 125, a double layer structure of the organic light emitting layer 125 and the electron transport layer 127. The second electrode layer 129, that is the cathode electrode, may be formed by depositing materials having a low work function such as a metal, for example Mg/Ag, Mg, Al or alloys thereof.

When a voltage is applied to the organic light emitting device 120 to bias the first electrode layer 121 as an anode and the second electrode layer 129 as a cathode, holes inserted from the first electrode layer 121 and electrons inserted from the second electrode layer 129 are recombined in the organic light emitting layer 125, and thus the energy level in the organic light emitting layer 125 decreases from an excited state to a ground state. Thus, the organic light emitting layer 125 emits light having a specific wavelength corresponding to the energy difference between the excited state and the ground state.

A sealing protection layer 130 is formed to cover lateral and upper sides of the organic light emitting device 120. Specifically, the sealing protection layer 130 isolates the organic thin film layer 122 and the second electrode layer 129 formed on the first electrode layer 121 from external gases. The sealing protection layer 130 may be formed by depositing LaF₃ along the outer surface of the organic light emitting device 120 to have a predetermined thin film thickness. The LaF₃ is not dissolved in moisture, and prevents impurities such as moisture or oxygen from penetrating into and reacting with the organic light emitting device 120, thereby increasing durability of the organic light emitting device 120 against moisture and oxygen.

In FIG. 2, the edges of the first electrode layer 121 are not covered by the sealing protection layer 130, however, the present invention is not limited thereto. For example, the sealing protection layer 130 may cover the entire structure of the organic light emitting device 120 including the entire major surface area of first electrode layer 121 that is opposite a major surface area attached to the insulation substrate 110.

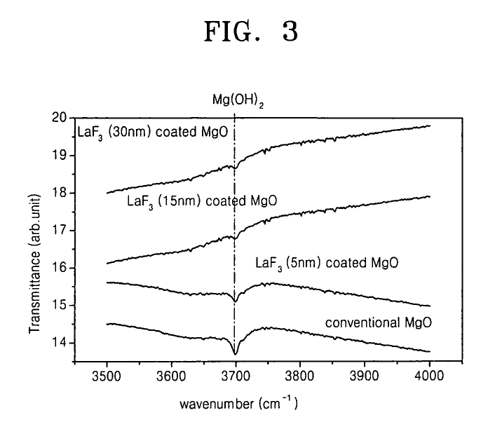

FIG. 3 is a graph illustrating the degree of protection against moisture of LaF₃ layers. Fourier transform infrared spectroscopy (“FT-IR”) was employed to obtain the results illustrated in FIG. 3. In the FT-IR, infrared rays with various wavelengths are radiated on a sample and then an absorption peak is detected, thereby detecting whether or not a specific material exists in the sample.

An MgO layer having a thickness of 500 nm was formed on a silicon substrate, and a LaF₃ layer is formed on the MgO layer as a protecting layer against moisture. The degree of moisture absorbtion of the MgO layer is measured by the FT-IR. MgO is not resistant to moisture and reacts with moisture to form Mg(OH)₂. The LaF₃ layer formed on the MgO layer can prevent the reaction between the MgO layer and the moisture.

FIG. 3 illustrates transmittance profiles of a conventional MgO layer on which a LaF₃ layer is not formed (e.g., LaF₃ layer is absent), and LaF₃ coated on MgO layers having a LaF₃ layer thickness of 5 nm, 15 nm, and 30 nm. In the conventional MgO layer, an absorption peak appears at about a wavenumber of 3700 cm⁻¹ when the transmittance rapidly drops. The absorption peak is caused by the inherent vibration mode of an OH-group, and indicates the reaction between the MgO layer and moisture. The absorption peak decreases as the thickness of the LaF₃ layer increases, as illustrated in FIG. 3. When the thickness of the LaF₃ layer is equal to 30 nm, the absorption peak disappears such that the LaF₃ layer is thick enough to completely prevent the penetration of moisture. Thus, the results can be used to determine a standard thickness of the LaF₃ layer. The LaF₃ layer may have a thickness of at least 30 nm as a protecting layer, for example, about 50 nm to about 1000 nm.

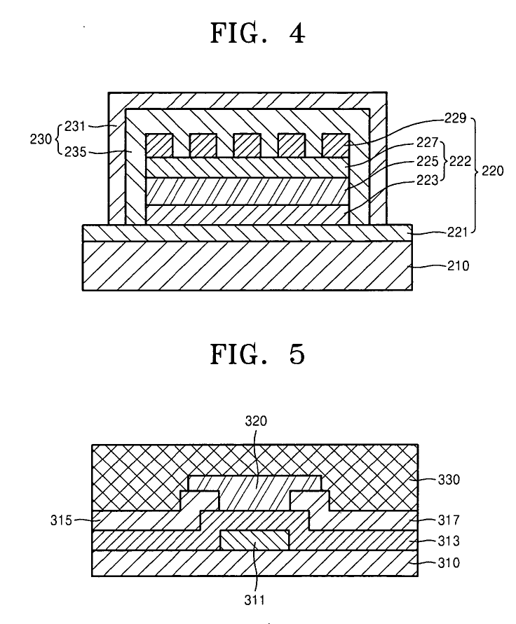

FIG. 4 is a cross-sectional view of an organic electro-luminescence display apparatus according to another exemplary embodiment of the present invention. The organic electro-luminescence display apparatus includes an organic light emitting device 220 formed on an insulation substrate 210, a sealing protection layer 230 covering and sealing the organic light emitting device 220. The organic light emitting device 220 includes a first electrode layer 221 supplying holes, a second electrode layer 229 supplying electrons, and an organic thin film layer 222, which is disposed between the first electrode layer 221 and the second electrode layer 229. The organic light emitting device 220 emits light through the recombination of the inserted holes and the inserted electrons.

In the current exemplary embodiment, the sealing protection layer 230 has a stacked structure including two or more different layers, one layer including a LaF₃ layer. Specifically, the sealing protection layer 230 in FIG. 4 includes an inner interlayer 235 and an outer LaF₃ layer 231. The LaF₃ layer 231 prevents the penetration of moisture or oxygen that can react with the organic light emitting device 220, as described in the previous exemplary embodiment of FIG. 2, thereby preventing corrosion or oxidation of the organic light emitting device 220 and the formation of dark spots not having a display function.

The interlayer 235 is formed between the organic light emitting device 220 emitting light and the LaF₃ layer 231 functioning as a protection layer and increasing the bonding attachment between the organic light emitting device 220 and the LaF₃ layer 231. If the LaF₃ layer 231 is formed directly on the organic light emitting device 220 as in the prior art, the LaF₃ layer may not completely seal the outside of the organic light emitting device 220 because of the material characteristic differences between the LaF₃ layer 231 and the material in the organic light emitting device 220, thereby generating a gap therebetween. The interlayer 235 is formed to prevent the generation of the gap between the LaF₃ layer 231 and the organic light emitting device 220. The interlayer 235 is formed of an organic material or an inorganic material, and may be formed of a material which has similar material characteristics to LaF₃ and is easily attached to LaF₃.

When the interlayer 235 covering the organic light emitting device 220 with the LaF₃ layer 231 is an inorganic layer, the interlayer 235 may be formed of silicon oxide or silicon nitride, for example, SiO₂ or Si₃N₄. When the interlayer 235 is an organic layer, the interlayer 235 may be formed of a high molecular organic material, for example, polythiophene (PTh), polyfluorene (PF), polyarylenevinylene (PAV), or a precursor thereof, or a low molecular organic material, for example, copper(ll) pthalocyanine (CUPc), tris(8-quinolinolato)aluminum (Alq3), or a precursor thereof, but the present invention is not limited thereto.

The LaF₃ layer 231 may be formed of a thick film having a predetermined thickness to prevent the penetration of an external gas such as oxygen or moisture. However, a single process may not form the thick film for the LaF₃ layer 231 because of process factors or material characteristics of the LaF₃. A sealing protection layer having a stacked structure may solve this problem. That is, an interlayer, which is easily attached to the LaF₃ layer, is formed between LaF₃ layers, and thus a sealing protection layer having a desired thickness can be provided.

The sealing protection layer according to exemplary embodiments of the present invention includes a LaF₃ layer, and has a stacked structure of the LaF₃ layer and an organic layer, a stacked structure of the LaF₃ layer and an inorganic layer, or a stacked structure of the LaF₃ layer, the organic layer and the inorganic layer. That is, the sealing protection layer 230 in FIG. 4 includes an interlayer 235, which is an organic layer or an inorganic layer and formed on the organic light emitting device 220, and a LaF₃ layer 231 formed on the interlayer 235. However, the present invention is not limited thereto. For example, an organic layer is formed on the light emitting device 220, and then a LaF₃ layer and an inorganic layer are sequentially formed on the organic layer. Alternatively, for example, an inorganic layer is formed on the light emitting device 220, and then a LaF₃ layer and an organic layer are sequentially formed on the organic layer. For both cases, the LaF₃ protects the light emitting device 220 from penetration of external moisture and oxygen. The inorganic layer may be formed of silicon oxide or silicon nitride, and the organic layer may be a high molecular organic layer or a low molecular organic layer.

The LaF₃ layer may be formed using one deposition method selected from the group consisting of physical vapor deposition (“PVD”) including ion beam deposition and chemical vapor deposition (“CVD”) including low pressure CVD (“LPCVD”) and plasma enhanced CVD (“PECVD”). To optimize conditions for forming the LaF₃ layer, an inorganic layer or an organic layer is formed and then the LaF₃ layer is formed thereon.

FIG. 5 is a cross-sectional view of an organic thin film transistor according to yet another exemplary embodiment of the present invention. The organic thin film transistor includes a gate electrode 311 formed on a predetermined region of an insulation substrate 310, an organic insulation layer 313 covering and insulating the gate electrode 311, a source electrode 315 and a drain electrode 317 formed on the organic insulation layer 313, an organic semiconductor layer 320 formed on the organic insulation layer 313 to connect the source electrode 315 and the drain electrode 317, and a passivation layer 330 formed on the organic semiconductor layer 320.

The insulation substrate 310, whereon the organic thin film transistor is formed, supports an organic thin film structure. The insulation substrate 310 is formed of glass, silicon, or flexible plastic. The gate electrode 311 formed on the insulation substrate 310 can be formed of a typical metal electrode material, for example, Au, Ag, Al, Cu, Ni, or an alloy thereof. The gate electrode 311 may be formed by vacuum depositing an electrode material onto a predetermined region of the insulation substrate 310. The organic insulation layer 313, covering and insulating the gate electrode 311, is formed on the insulation substrate 310. The organic insulation layer 313 may be formed of polyimide, benzocyclobutene (BCB), or photoacryl.

The source electrode 315 and the drain electrode 317 each are formed on a predetermined region of the organic insulation layer 313. The source electrode 315 and the drain electrode 317 may be conductive layers which are vacuum deposited onto the organic insulation layer 313 as a predetermined pattern and may be formed of typical metal electrode materials like the above-described gate electrode 311. The organic semiconductor layer 320 is formed on the organic insulation layer 313 and forms a conduction pathway between the source electrode 315 and the drain electrode 317. The organic semiconductor layer 320 may be formed of a commonly used material, for example, pentacene, polyacetylene, polyaniline, or a precursor thereof.

The passivation layer 330 covers and seals the inner thin films to prevent the metallic electrodes from oxidation or corrosion and reaction of the organic material layer with oxygen and moisture, such that the characteristics of the organic thin film transistor are not degraded. The passivation layer 330 is formed by depositing LaF₃ to a predetermined thickness on upper regions of the source electrode 315, the drain electrode 317 and the organic semiconductor layer 320. The LaF₃ is not dissolved in moisture, and prevents impurities such as moisture or oxygen from penetrating into and reacting with the inner thin films, thereby increasing durability of the organic thin film transistor.

The passivation layer of the present invention includes a LaF₃ layer. The passivation layer may be a LaF₃ monolayer layer, as illustrated in FIG. 5, or a multi-layer in which a LaF₃ layer and an organic layer and/or an inorganic layer are stacked. When the passivation layer is a multi-layer, one of or both of the organic layer and the inorganic layer are formed on the upper side or lower side of the LaF₃ layer. For example, an organic layer having similar material characteristics to an organic semiconductor is formed on the organic semiconductor layer 320, and then a passivation layer in which LaF₃ layers are stacked is formed on the organic layer. In this case, since the organic material layers have similar material characteristics, they are better attached to each other. The organic or inorganic layer forming the passivation layer 330 with the LaF₃ layer can be formed of the same materials as the sealing protection layer 230 described above with respect to FIG. 4. That is, the inorganic layer may be formed of silicon oxide or silicon nitride, for example, SiO₂ or Si₃N₄. The organic layer may be formed of a high molecular organic material, for example, polythiophene (PTh), polyfluorene (PF), polyarylenevinylene (PAV), or a precursor thereof, or a low molecular organic material, for example, copper(II) pthalocyanine (CUPc), tris(8-quinolinolato)aluminum (Alq3), or a precursor thereof, but the present invention is not limited thereto.

Based on the results in FIG. 3, to effectively prevent the penetration of impurities such as oxygen and moisture, the passivation layer 330 of the present invention may have a thickness of at least 30 nm or more, for example, about 50 nm to about 1000 nm. In the exemplary embodiment of FIG. 5, the passivation layer 330 is formed on the organic semiconductor layer 320, but the present invention is not limited thereto. That is, if the passivation layer 330 includes a LaF₃ layer as an external gas protection layer, the passivation layer 330 can be formed on any portion of the organic thin film structure, for example, on the organic insulation layer 313.

In the organic electro-luminescence display apparatus and the organic thin film transistor for the same according to the present invention, a vulnerable inner thin film structure is sealed with a LaF₃ layer having high resistivity against the penetration of moisture or oxygen, thereby preventing the degradation of the display device characteristics such as the generation of dark spots, which substantially reduce a display function and light luminance of the display device.

The organic electro-luminescence display apparatus according to the present invention does not require any additional protecting structure for sealing the organic light emitting device and any additional processes for sealing the device and preparing moisture absorbents, thereby reducing the manufacturing costs thereof.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic electro-luminescence display apparatus comprising:
a first electrode layer which supplies holes;
a second electrode layer which supplies electrons;
an organic thin film layer disposed between the first electrode layer and the second electrode layer, the organic thin film layer emits light through the recombination of the holes and the electrons; and
a sealing protection layer which insulates at least the second electrode layer and the organic thin film layer from an external gas,
wherein the sealing protection layer comprises at least a LaF₃ layer.

2. The apparatus of claim 1, further comprising an insulation substrate defining a supporting structure,
wherein the first electrode layer, organic thin film layer, and second electrode layer are sequentially stacked on the insulation substrate, and
wherein the sealing protection layer seals an outer region ranging from the lateral sides of the organic thin film layer and the second electrode layer to the upper sides of the second electrode layer.

3. The apparatus of claim 1, wherein the sealing protection layer is a monolayer of the LaF₃ layer.

4. The apparatus of claim 1, wherein the sealing protection layer has a multilayer structure including at least two layers of the LaF₃ layer and one of an organic layer and an inorganic layer.

5. The apparatus of claim 4, wherein the inorganic layer is formed of one of silicon nitride and silicon oxide.

6. The apparatus of claim 1, wherein the sealing protection layer has a multilayer structure including at least three layers of the LaF₃ layer, an organic layer and an inorganic layer.

7. The apparatus of claim 6, wherein the inorganic layer is formed of one of silicon nitride and silicon oxide.

8. The apparatus of claim 1, wherein the sealing protection layer contacts the organic thin film layer and the second electrode layer.

9. The apparatus of claim 1, wherein the LaF₃ layer has a thickness of at least 30 nm.

10. The apparatus of claim 1, wherein the LaF₃ layer is formed using one deposition method selected from the group consisting of physical vapor deposition (PVD) including ion beam deposition and chemical vapor deposition (CVD) including low pressure CVD (LPCVD) and plasma enhanced CVD (PECVD).

11. An organic thin film transistor comprising:
a gate electrode formed on an insulation substrate;
an organic insulation layer covering the gate electrode;
a source electrode and a drain electrode formed on the upper surface of the organic insulation layer; and
an organic semiconductor layer formed on the source and drain electrodes, wherein the organic thin film transistor comprises:
a passivation layer which includes at least a LaF₃ layer, the LaF₃ layer is formed on the upper surface of the organic insulation layer or on the upper surface of the organic semiconductor layer.

12. The organic thin film transistor of claim 11, wherein the passivation layer is a monolayer of the LaF₃ layer.

13. The organic thin film transistor of claim 11, wherein the passivation layer has a multilayer structure including at least two layers of the LaF₃ layer and one of an organic layer and an inorganic layer.

14. The organic thin film transistor of claim 13, wherein the inorganic layer is formed of one of silicon nitride and silicon oxide.

15. The organic thin film transistor of claim 11, wherein the passivation layer has a multilayer structure including at least three layers of the LaF₃ layer, an organic layer and an inorganic layer.

16. The organic thin film transistor of claim 15, wherein the inorganic layer is formed of one of silicon nitride and silicon oxide.

17. The organic thin film transistor of claim 11, wherein the passivation layer covers the source and drain electrodes and the organic semiconductor layer formed between the source and drain electrodes.

18. The organic thin film transistor of claim 11, wherein the LaF₃ layer has a thickness of at least 30 nm.

19. The organic thin film transistor of claim 11, wherein the LaF₃ layer is formed using one deposition method selected from the group consisting of physical vapor deposition (PVD) including ion beam deposition and chemical vapor deposition (CVD) including low pressure CVD (LPCVD) and plasma enhanced CVD (PECVD).
